(19) United States
(12) Patent Application Publication
(10) Pub. No.: US 2013/0207248 A1
(43) Pub. Date: Aug. 15, 2013

(54) DEVICE INCLUDING ELECTRICAL, ELECTRONIC, ELECTROMECHANICAL OR ELECTROOPTICAL COMPONENTS HAVING REDUCED SENSITIVITY AT A LOW DOSE RATE

(71) Applicants: Alain Bensoussan, Odars (FR); Ronan Marec, Escalquens (FR)

(72) Inventors: Alain Bensoussan, Odars (FR); Ronan Marec, Escalquens (FR)

(73) Assignee: THALES, Neuilly Sur Seine (FR)

(21) Appl. No.: 13/579,519

(22) PCT Filed: Feb. 8, 2011
(86) PCT No.: PCT/EP2011/051774

§ 371 Date: Sep. 5, 2012

(30) Foreign Application Priority Data
Feb. 16, 2010 (FR) 10/00647

(51) Int. Cl. H01L 23/552; H01L 23/00

(52) U.S. Cl. CPC H01L 23/552; H01L 23/564
USPC 257/660; 438/115

(57) ABSTRACT

A device for a space application, the device including at least one electronic, electromechanical or electro-optical component encapsulated in a package, the package comprising a hydrogen getter guaranteeing resistance to ionizing radiation and in particular at a low dose rate, responsible for ELDRS behavior. In one embodiment, the package may include a cap that hermetically seals a package base. Advantageously, a process may be implemented in order to promote the migration of hydrogen molecules or H+ protons toward the getter and trap said molecules or protons in the getter for the useful lifetime of the component.

The present invention relates to a device, notably a device comprising electronic, electromechanical or electro-optical components, the device reducing the dose sensitivity of the components, in particular in a low dose rate environment. The invention is applicable to integrated circuits and discrete components (such as transistors and diodes, for example) that are encapsulated in hermetic packages and notably used in radiation environments, for example in devices used in space applications such as satellites.

Many applications, notably in the aerospace field, use electrical, electronic, electromechanical or electro-optical components. In these applications these components are commonly encapsulated in hermetic packages. Most components used, whether discrete components or integrated circuits, are produced in silicon-based materials in known technologies such as, for example, the active bipolar silicon-based technology, the technology known as CMOS (complementary metal oxide semiconductor) technology, BiCMOS (bipolar CMOS) technology, or even MOSFET (metal oxide semiconductor field-effect transistor) technology. A problem with components fabricated in these technologies (principally in BiCMOS and bipolar technologies) is their high sensitivity to ionizing radiation and in particular their enhanced sensitivity at low dose rates or ELDRS (enhanced low dose rate sensitivity). Specifically, such components notably comprise protective layers such as passivation layers, these layers being permeable to atomic hydrogen. Thus, the main degradation mechanism of these components is related to the presence of atomic hydrogen H⁺, or positive or negative ions, migrating through passivation layers toward the active zones of the semiconductor or accumulating on the surface of the passivation layers in line with the active zone of the semiconductor-comprising components and thus modifying their original electrical and technological characteristics. In CMOS technologies it is known that hydrogen trapped in sealed packages may affect the total dose resistance and the behavior of transistors and integrated circuits after annealing. Thus, components which have been subjected to a 100% hydrogen atmosphere are clearly more sensitive to total radiation dose.

In addition, it is known that, for components produced in bipolar technology, notably encapsulated in flat packages, i.e. “flatpack” packaging for example, the presence of hydrogen can lead to enhanced sensitivity to total dose, but also to enhanced sensitivity at low dose rates.

Finally, it is also known that the radiation dose behavior of integrated circuits produced in silicon-based bipolar technology in the presence of hydrogen molecules may differ depending on the processes used to produce the components.

All known results show that components produced in bipolar technology may exhibit a good resistance to high and low dose rates when their fabrication process terminates in a metallization step. It is the steps that come after the metallization: notably, the nature of the passivation and the deposition process; heat treatments carried out during encapsulation in the package or during preconditioning; and burn-in, and of course the presence of hydrogen molecules in the package atmosphere, that may reduce the dose resistance of the component.

It has not been ruled out that the presence of H⁺ protons initially trapped in the passivation layers of the components may also be the cause of the degradation. There are a number of possible sources of the presence of contaminant H⁺ ions:
a first source is the residual atmosphere inside the package as was mentioned above. In this case, H₂ covalent bonds may be broken under the effect of a number of factors of relative importance. These factors may be thermal effects; radiation effects; electric fields associated with polarization of the component; and the presence of metals used in the metal lines deposited on the silicon, these lines notably allowing the active transistor structure to be polarized. These metals act as catalysts promoting breaking of the molecular bond and formation of H⁺ protons—this is the case for metals such as platinum, tantalum, palladium or even titanium;
a second source is atomic hydrogen present in the passivation layers, typically made of silica SiO₂, deposited during the processing steps for producing these layers. In this case, Van der Waals bonds are concerned, the bond strength of which is much lower than that of covalent H₂ bonds. The H⁺ ions are also more mobile and migrate into the passivation under the influence of polarizing electric fields and accumulate, by electrical attraction, in zones polarized with a negative voltage; and
also, other positive or negative ion sources, such as for example sources of Na⁺, K⁺, NH₃⁺ and OH⁻ ions etc., are considered to be interfering elements with respect to semiconductor-comprising components, and capable of interfering with the performance of these devices in normal use, under direct or indirect polarization, due to the field of the parasitic local potential generated by the presence of these charge carriers above the active zones. Thus, the presence, in these components, of such parasitic charge carriers may also have an adverse effect if said components are subjected to an ionizing radiation environment, such as the space environment in which satellites operate. Ionizing radiation thus promotes accumulation of such sources of potential and may amplify the drift observed for sensitive components.

The main source is therefore the presence of volatile and mobile ions inside the hermetic package and, in certain cases, particularly the presence of H⁺ protons generated by decomposition of residual hydrogen gas present in the atmosphere of the package.

In order to reduce degradation in the presence of doses of radiation, notably degradation of components produced in bipolar or CMOS technology encapsulated in hermetic packages, a number of solutions are known in the prior art. A first solution consists in carrying out low dose rate characterization testing of integrated circuits. However, it is not possible to simulate the actual conditions that the components will be subjected to, these conditions notably comprising relatively long term exposure—typically several years, for example, for satellite applications—to very low dose rates. Thus, it is necessary, if the results of such characterization are to be conclusive, for the testing to be carried out over very long periods of time, typically several months. Carrying out testing over such a long period of time has an adverse effect on the time taken to produce systems for space applications and represents a significant additional cost.

A second known solution, which may be implemented by component manufacturers, consists in removing residual hydrogen, possibly contaminating the semiconductor component, using a manufacturing process that is exempt from hydrogen traces. Manufacturers may also guarantee a total dose resistance, which must be certified by test reports provided with the components. In the case where, for practical reasons, the manufacturer has carried out high dose rate testing, additional low dose rate testing must also be performed. This option again has an adverse effect on production time and is associated with a significant additional cost. In any case, such a solution also has the drawback of increasing component cost and requiring long and expensive testing with the aim of ensuring the quality of the delivered components.

One aim of the present invention is to alleviate at least the aforementioned drawbacks by providing a device comprising electrical, electronic, electromechanical or electro-optical components encapsulated in hermetic packages that reduce the sensitivity of these devices to total dose.

For this purpose, the subject of the invention is a device for a space application, which device is able to be subjected to ionizing radiation, the device comprising at least one electronic, electromechanical or microelectromechanical, or electro-optical or microelectro-optical component encapsulated in a hermetic package, characterized in that the package furthermore comprises an absorbing/adsorbing element called a “getter”, such as a hydrogen getter, that is able to trap positive or negative volatile, mobile ions and keep them absorbed or adsorbed so as to guarantee the resistance of said at least one component to ionizing radiation, said at least one component essentially being a semiconductor component produced in a silicon-based active bipolar, MOS, CMOS or BiCMOS technology.

In one embodiment of the invention, the getter may be a hydrogen getter.

In one embodiment of the invention, the device may be characterized in that the package comprises a package base that is hermetically sealed by a cap, the getter being added to the internal surface of the cap.

In one embodiment of the invention, the device able to be subjected to ionizing radiation may be characterized in that the cap and the package base each comprise a ceramic and/or metal body.

In one embodiment of the invention, the device able to be subjected to ionizing radiation may be characterized in that the cap and/or the package base is covered with a metal top coat.

In one embodiment of the invention, the device able to be subjected to ionizing radiation may be characterized in that the cap comprises a body adhesively bonded to a thickness of hydrogen getter material, the hydrogen getter material being placed substantially on the internal part of the cap.

In one embodiment of the invention, the device able to be subjected to ionizing radiation may be characterized in that the internal cavity of the hermetic package comprises a partial vacuum created by a degassing process before the hermetic package is sealed.

In one embodiment of the invention, the device able to be subjected to ionizing radiation may be characterized in that the migration of H+ protons present in the component and the package is promoted by polarizing active zones of the component.

In one embodiment of the invention, the device able to be subjected to ionizing radiation may be characterized in that the metal body is made of an iron-nickel-cobalt alloy.

In one embodiment of the invention, the device able to be subjected to ionizing radiation may be characterized in that the top coat is formed by electrodepositing a thickness of gold.

In one embodiment of the invention, the device able to be subjected to ionizing radiation may be characterized in that the hydrogen getter is made of a titanium-, platinum-, palladium- and/or vanadium-based material.

In one embodiment of the invention, the device able to be subjected to ionizing radiation may be characterized in that the hydrogen getter is adhesively bonded, soldered or securely fastened in any way known per se to the lower face of the cap.

In one embodiment of the invention, the device able to be subjected to ionizing radiation may be characterized in that the hydrogen getter is incorporated into the structure of the cap and/or of the package base.

In one embodiment of the invention, the device able to be subjected to ionizing radiation may be characterized in that the hydrogen getter is incorporated into the top coat of the cap and/or of the package base.

In one embodiment of the invention, the device able to be subjected to ionizing radiation may be characterized in that the hydrogen getter is formed by depositing thin films of titanium, platinum, palladium and/or vanadium in succession directly on the body of the cap and/or the body of the package base in a vacuum chamber.

One advantage of the present invention lies in the fact that the device according to one of the described embodiments may guarantee a good resistance, notably for the active components that it comprises, when the latter are exposed to ionizing radiation, in particular at a low dose rate, responsible for ELDRS behavior, even when these active components are not initially designed, developed and tested for space applications that are demanding from the point of view of total dose resistance. Thus, it notably becomes possible, by virtue of the present invention, to supply, to place, in a package according to the device described above, subject of the present invention, and to use, to manufacture systems intended for space applications, less expensive Si bipolar, MOS, CMOS, BiCMOS chips that were initially designed for terrestrial applications but that cannot be used in a radiation environment such as space.

Other features and advantages of the invention will become apparent on reading the description, given by way of example, and with regard to the appended drawings, which show:

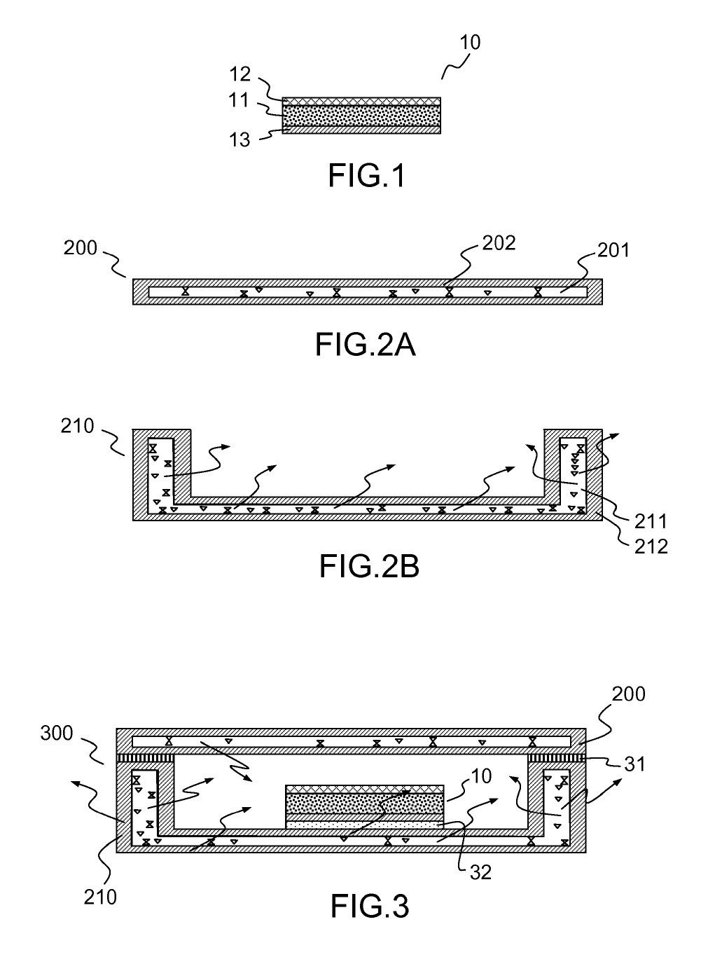

FIG. 1, a cross-sectional view of an exemplary integrated circuit known per se in the prior art;

FIGS. 2a and 2b, cross-sectional views of a metal cap and a metal base, respectively, forming a package known per se in the prior art;

FIG. 3, a cross-sectional view of the integrated circuit placed in the, hermetically sealed, package;

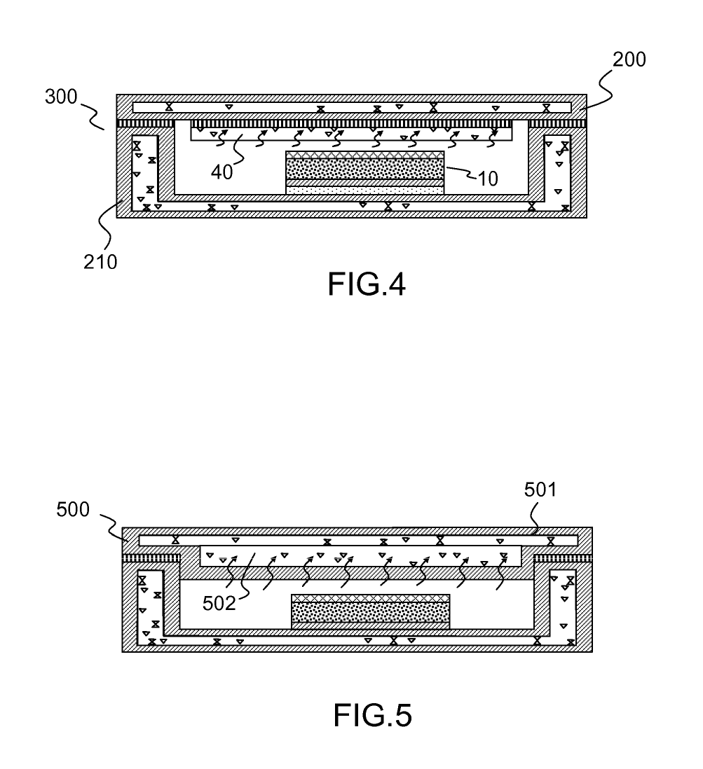

FIG. 4, a cross-sectional view of a device comprising the integrated circuit and the hermetic package, in an exemplary embodiment of the invention; and

FIG. 5, a cross-sectional view of a device comprising the integrated circuit and the hermetic package, according to another exemplary embodiment of the invention.

FIG. 1 shows a cross-sectional view of an exemplary integrated circuit known per se in the prior art.

One component 10, in the example illustrated in the figure a silicon-based integrated circuit produced in CMOS or bipolar technology, schematically consists of a silicon substrate 11, in the example in the figure comprising a metallization layer 13 on its lower face, substrate into which active layers are diffused, said layers being connected together by metal lines and deposited on oxide layers, the whole being covered with one or more passivation layers 12. The configuration of the component 10 illustrated in the figure is given merely by way of example, and other typical component configurations may be envisioned. The purpose of the passivation layer 12 is to protect the component 10 during manufacturing process steps carried out after the component 10 itself has been fabricated. The component 10 is for example typically about a few hundred microns in thickness.

After the component 10 has been produced, protons H⁺ may be trapped in the passivation layer 12.

FIGS. 2a and 2b show a cross-sectional view of a cap and a base, respectively, the cap and base forming a package known per se in the prior art.

In the example illustrated in FIG. 2a, a cap 200 may comprise a body 201 covered with a top coat 202. The body 201 may typically be made of a material with a low thermal expansion coefficient, for example such as a ceramic material or even an iron-nickel-cobalt alloy. The top coat 202 may for example be formed by electrodepositing a small thickness of gold. For example, the typical thickness of the body 201 may be about a millimeter and the thickness of the top coat 202 about a micron. The cap 200 may for example also be made of a ceramic material or a metal or metal alloy.

In the example illustrated in FIG. 2b, a package base 210 may similarly comprise a body 211 coated with a thin top coat 212. The package base 210 may be covered with the cap 200, and these two elements may be soldered together in order to hermetically seal the package thus formed, as will be described in more detail below with reference to an example illustrated in FIG. 3.

Protons H⁺ or hydrogen may be trapped, notably in the constituent materials of the cap 200 and package base 210. In the example illustrated in FIG. 2 and the following figures, protons H⁺ are represented by triangles, one corner of which points downward. Also, hydrogen molecules H₂ are represented by triangles, one corner of which points upward, surmounted by triangles, one corner of which points downward. Arrows represent the migration of protons H⁺ and hydrogen molecules H₂ over time.

Of course, it will be understood that the structures illustrated in FIGS. 2a and 2b are given merely by way of example. Notably, the presence of a top coat 202, 212 on the cap 200 and the package base 210 is optional.

FIG. 3 shows a cross-sectional view of the integrated circuit placed in the hermetically sealed package.

The component 10, for example the integrated circuit such as described above with reference to FIG. 1, may be placed at the bottom of the package base 210, such as was described above with reference to FIG. 2. The component 10 may be soldered or indeed adhesively bonded to the bottom of the package base 210. In the example illustrated by the figure, a layer of solder 32 has been shown under the component 10. The cap 200 and the package base 210 may be soldered together, for example via a solder bead 31, in order to form a hermetic package 300. Typically, the operations used to mount the component 10 in the package may be carried out in a controlled atmosphere, for example in an oven. According to known techniques, it is for example possible to carry out these operations in a mainly nitrogen atmosphere, so as to remove oxygen present in the hermetic package 300 with the aim of reducing oxidation of components encapsulated in the package.

The solution provided by the present invention is based on the idea of placing a permanent absorbing/adsorbing element or “getter”, such as for example a hydrogen getter, in the hermetic package 300. In the following, by way of a nonlimiting example of the present invention, reference will be made to a hydrogen getter, it being understood that the getter may be designed to promote absorption/adsorption of other positive or negative ions. Generally, the getter may consist of a metal alloy or of a macromolecular compound capable of trapping, on its surface or in its volume, positive or negative volatile, mobile ions such as for example Na⁺, K⁺, H⁺, NH₃⁺, OH⁻, H₃O⁺, CO⁺, CO₂⁺ ions etc., and to keep them absorbed/adsorbed over time and under the relatively stable temperature and pressure conditions of normal operation in a satellite, and the absorbing/adsorbing parts not requiring regenerating (notably by thermal annealing or by vaporization of an alloy) during their use. The hydrogen getter is enclosed inside the hermetic package 300 and has a size and composition that are optimized so as to guarantee an as low as possible permanent residual internal content at least for the expected lifetime of the component. Materials enabling effective gettering and retention of hydrogen are known per se from the prior art.

Getters, notably hydrogen getters, known in the prior art are intended for terrestrial applications, in which applications active components made in silicon bipolar, MOS, CMOS or BiCMOS technologies are not adversely affected by the presence of hydrogen. Known hydrogen getters are used in devices based on the III-V semiconductors, such as GaAs (gallium arsenide), which are known to be sensitive to the influence of hydrogen. Thus documents describing these getters exclude using silicon bipolar, MOS, CMOS or BiCMOS production technologies.

An exemplary configuration is described below with reference to FIG. 4, which shows a cross-sectional view of a device comprising the integrated circuit and the hermetic package, in an exemplary embodiment of the invention.

The hermetic package 300, formed by the package base 210 covered with the cap 200, comprises the component 10 in a configuration such as described above with reference to FIG. 3. Furthermore, a hydrogen getter 40 may also be incorporated in the hermetic package 300. In the exemplary embodiment illustrated in the figure, the hydrogen getter 40 is placed under the cap 200. The hydrogen getter 40 is for example adhesively bonded, soldered or securely fastened in any way known per se to the lower face of the cap 200. In the example illustrated in the figure, a solder layer is shown between the hydrogen getter 40 and the cap 200.

The getter (the hydrogen getter 40 in the examples illustrated in the figures) is capable of adsorbing and absorbing any trace ions present in the sealed cavity: whether residual H₂ gas or H₂ gas generated by dynamic chemical processes or volatile ions present in the hermetic cavity formed by the hermetic package 300.

Regarding a hydrogen getter in particular, the advantage of placing the hydrogen getter 40 in the hermetic package 300 is that a dynamic chemical reaction is promoted which has an absorption rate that is higher than the natural rate at which hydrogen degasses. Thus the hydrogen getter 40 must have good absorption characteristics and good hydrogen retention characteristics. The hydrogen getter 40 may typically take the form of a sheet based on a combination of metals, for example such as titanium, platinum, palladium, vanadium or even an alloy of these metals. Typically, this metal sheet may be about a few tenths of a millimeter in thickness.

Advantageously, a specific process may be implemented, in order to promote extraction of the hydrogen notably present near the active zones of the passivation layers of the components encapsulated in the hermetic package 300. The process may for example comprise a prior heating step, possibly carried out before the hermetic package 300 has been sealed. The process may also include a degassing step before the hydrogen getter 40 has been put in place and the hermetic package 300 has been sealed. For example, a vacuum or partial vacuum may be created in the hermetic package 300 during the sealing operation so as to promote subsequent migration of the hydrogen toward the hydrogen getter 40. It is desirable to reduce the hydrogen content present in the package to as low as possible a level, which level will be maintained, by virtue of the hydrogen getter 40, throughout the lifetime of the component.

Advantageously, it is also possible, for example, to temperature polarize the component so as to promote migration of protons through the passivation and thus more effectively extract these protons toward the hydrogen getter 40. This process may also be combined with the steps described above.

Advantageously, it is furthermore possible to improve the effectiveness of the hydrogen getter 40 by way of a suitable geometry. For example, a “waffle”-shaped structure may be used, providing the hydrogen getter 40 with a high surface/volume ratio, with the aim of increasing the amount of hydrogen absorbed.

In one embodiment of the invention, it is also possible to incorporate the hydrogen getter in the very structure of the hermetic package 300. For example, it is possible to produce a package cap having a suitable structure and containing a material having the required gettering properties.

In an alternative embodiment of the invention, it is also possible, if required, to incorporate the hydrogen getter in the very structure of the top coat 202, 212 covering the cap 200 and the package base 210, respectively. For example, thin films of titanium, platinum, palladium and/or vanadium may be directly deposited in succession on the body of the cap 201 or the body of the package base 211, for example in a vacuum chamber.

FIG. 5, described below, shows a cross-sectional view of a device, comprising the integrated circuit and the hermetic package, according to such an embodiment of the invention.

In the embodiment illustrated in FIG. 5, in a configuration that is moreover equivalent to the configuration described above with reference to FIG. 4, it is specifically possible not to use a discrete hydrogen getter 40. This is possible because a cap 500 has been used in which a material has been incorporated having the properties of the hydrogen getter 50. For example, the cap 500 may consist of a body 501 made either of an iron-nickel-cobalt alloy or of a ceramic, the body 501 being adhesively bonded to a thickness of getter material 502. The cap 500 may then, in a similar way to the embodiments described above, be soldered to the package base. Thus, protons H⁺ and hydrogen molecules H₂ present in the body 501 may naturally migrate toward the getter material 502. Also, protons H⁺ and hydrogen molecules H₂ present in the internal cavity of the package, in the passivation layers of the components and in the package base, may migrate toward the getter material 502, in a similar way to described for the configuration in FIG. 4. Also, it is advantageously possible to promote the migration of the ions, protons H⁺ for example, and hydrogen molecules toward the getter material 502 by implementing a suitable process, such as described above with reference to FIG. 4, comprising for example a step of degassing hydrogen by creating of a partial vacuum and/or forcing protons H⁺ to migrate by applying appropriate electric fields via reverse polarization of certain active zones of the components.

It will be noted that the present invention is mainly applicable to units comprising active electronic components comprising semiconductors produced using elements from Group IV (Si) of the periodic table, such as discrete transistors and diodes and integrated circuits produced in bipolar, MOS, MOSFET, CMOS technologies, etc.

One advantage provided by the invention lies in the fact that it allows the total ionizing radiation dose resistance of devices to be increased. It in particular allows ELDRS effects to be suppressed, and therefore provides the following advantages:
it makes it possible to use an equivalent nonhardened electronic function instead of the hardened components commonly used. Components are called “hardened” components when they have been specifically developed by their manufacturer to be able to resist a certain total dose without degrading. This makes substantial component cost savings possible;
it makes it possible to reduce system weight since, because the dose resistance has been increased, the amount of shielding can be greatly reduced;
it makes it possible to dispense with additional low dose rate testing of hardened components with a manufacturer guarantee based on high dose rate tests. This advantage notably concerns linear integrated circuits produced in bipolar or BiCMOS technology. This makes it possible to make savings in respect of the radiation lot acceptance testing carried out on these components; and
it makes it possible to reduce test duration, which may be extremely long and disadvantageous with respect to system manufacturing schedules. For example, the radiation testing that must be carried out on component batches supplied for space applications is defined in ESCC standard 22900 of the European Space Agency (ESA), and the US standard MIL 1019-7. For bipolar and BiCMOS technologies, these standards require testing to be carried out at a low dose rate. In particular, MIL standard 1019-7 notably requires testing to be carried out at a dose rate lower than 36 rad(Si)/hour. To carry out testing to 100 krad, a level commonly encountered by components in space applications, would involve irradiation for a minimum of four months. This time is added to the component supply time which is thus increased. The present invention makes it possible to avoid having to carry out lengthy testing at very low dose rates since only high dose rate testing is necessary, therefore reducing the component supply time and making it possible to more easily manage just in time supply scheduling.

It is also possible to envision extending the devices and processes described above to other technologies such as components based on II-VI and III-V semiconductors having a silica SiO₂ passivation layer or else a passivation layer based on silicon nitride Si₃N₄, such as integrated circuits used in microwave or even optoelectronic applications. This is because it is possible that the same mechanism may operate in other semiconductor-comprising devices employing a silicon-nitride Si₃N₄ based passivation the processing of which may also promote the presence of ion complexes.

1. A device for a space application, which device is able to be subjected to ionizing radiation, the device comprising:
at least one electronic, electromechanical or microelectromechanical, or electro-optical or microelectro-optical component encapsulated in a hermetic package, the package comprising a hydrogen getter,
wherein said at least one component comprises a semiconductor component produced in a silicon-based active bipolar, MOS, CMOS or BiCMOS technology.

2. (canceled)

3. The device as claimed in claim 1, further comprising a package base that is hermetically sealed by a cap, the getter being added to the internal surface of the cap.

4. The device as claimed in claim 3, wherein the cap and the package base each comprise a body made of at least one element among the group comprising ceramic and metal body.

5. The device as claimed in claim 4, wherein the body comprises an iron-nickel-cobalt alloy.

6. The device as claimed in claim 3, wherein at least one among the group comprising the cap and the package base is covered with a metal top coat.

7. The device as claimed in claim 3, wherein the top coat is formed by electrodepositing a thickness of gold.

8. The device as claimed in claim 3, wherein the cap comprises a body adhesively bonded to a thickness of getter material, the getter material being placed substantially on the internal part of the cap.

9. The device as claimed in claim 1, wherein the internal cavity of the hermetic package is configured to allow a partial vacuum to be created by degassing before the hermetic package is sealed.

10. The device as claimed in claim 1, wherein the device is configured so as to allow active zones of the component to be polarized so as to promote migration of H+ protons present in the component and the package.

11. The device as claimed in claim 1, wherein the hydrogen getter is made of a material based on at least one element among the group comprising titanium, platinum, palladium and vanadium.

12. The device as claimed in claim 4, wherein the hydrogen getter is adhesively bonded, soldered or securely fastened in any way known per se to the lower face of the cap.

13. The device as claimed in claim 4, wherein the hydrogen getter is incorporated into the structure of the cap or of the package base.

14. The device as claimed in claim 5, wherein the hydrogen getter is incorporated into the top coat of the cap or of the package base.

15. The device as claimed in claim 4, wherein the hydrogen getter is formed by depositing thin films of at least one element among the group comprising titanium, platinum, palladium and vanadium in succession directly on the body of the cap or the body of the package base in a vacuum chamber.
